(19) United States
(12) Patent Application Publication
(10) Pub. No.: US 2014/0103404 A1
(43) Pub. Date: Apr. 17, 2014

(54) REPLACEMENT GATE WITH AN INNER DIELECTRIC SPACER

(71) Applicant: INTERNATIONAL BUSINESS MACHINES CORPORATION, Armonk, NY (US)

(72) Inventors: Ying Li, Newburgh, NY (US); Ramachandra Divakaruni, Ossining, NY (US); Vijay Narayanan, New York, NY (US); Richard S. Wise, Newburgh, NY (US)

(73) Assignee: International Business Machines Corporation, Armonk, NY (US)

(21) Appl. No.: 13/653,658

(22) Filed: Oct. 17, 2012

(51) Int. Cl. H01L 29/78; H01L 21/283

(52) U.S. Cl. 257/288; 438/586; 257/E29.255; 257/E21.19

(57) ABSTRACT

After formation of source and drain regions and a planarization dielectric layer, a disposable gate structure is removed to form a gate cavity. A gate dielectric and a lower gate electrode are formed within the gate cavity. The lower gate electrode is vertically recessed relative to the planarization dielectric layer to form a recessed region. An inner dielectric spacer is formed within the recessed region by depositing a conformal dielectric layer and removing horizontal portions thereof by an anisotropic etch. An upper gate electrode is formed by depositing another conductive material within a remaining portion of the recessed region. A contact level dielectric layer is formed and contact structures are formed to the source and drain regions. The inner dielectric spacer prevents an electrical short between the gate electrode and a contact structure that partially overlies the gate electrode by overlay variations during lithographic processes.

### BACKGROUND

The present disclosure generally relates to semiconductor devices, and particularly to semiconductor structures having a replacement gate structure including a reversed dielectric spacer, and methods of manufacturing the same.

High gate leakage current of silicon oxide and nitrided silicon dioxide as well as depletion effect of polysilicon gate electrodes limits the performance of conventional semiconductor oxide based gate electrodes. High performance devices for an equivalent oxide thickness (EOT) less than 2 nm require high dielectric constant (high-k) gate dielectrics and metal gate electrodes to limit the gate leakage current and provide high on-currents. Materials for high-k gate dielectrics include ZrO₂, HfO₂, other dielectric metal oxides, alloys thereof, and their silicate alloys.

One of the structures intended to overcome the high gate leakage of a gate dielectric is a replacement gate structure, in which a disposable gate structure and source and drain regions are formed on a semiconductor substrate. The disposable gate structure is subsequently replaced with a permanent gate structure, which is referred to as a replacement gate structure. In the replacement gate integration scheme, electrical dopants in source and drain regions can be activated in a dopant activation anneal prior to formation of the replacement gate structure. Thermal cycling of the materials of a replacement gate structures can be performed at temperatures lower than the temperature for a dopant activation anneal, which is typically greater than 800° C. Thus, the replacement gate scheme allows use of gate materials that may not be stable at the temperature of a dopant activation anneal.

One of the challenges of a replacement gate scheme is weak corner insulation between the gate electrode and a contact structure for a source region or a drain region. This is because a gate trench formed by removing a disposable gate structure is replaced with a stack of a gate dielectric and a conductive material that constitutes a gate electrode. The gate electrode extends to the top of a gate spacer, and thus, a contact via can extend to a periphery of the gate electrode upon misalignment. Thus, an attempt to form self-aligned contact structures on a replacement gate structure can engender a significant probability of an electrical short between a gate electrode and a self-aligned contact structure.

### SUMMARY

After formation of source and drain regions and a planarization dielectric layer, a disposable gate structure is removed to form a gate cavity. A gate dielectric, at least one work function metal portion, and a lower gate electrode are formed within the gate cavity. The at least one work function metal portion and the lower gate electrode are-vertically recessed relative to the planarization dielectric layer to form a recessed region. An inner dielectric spacer is formed within the recessed region by depositing a conformal dielectric layer and removing horizontal portions thereof by an anisotropic etch. An upper gate electrode is formed by depositing another conductive material within a remaining portion of the recessed region. A contact level dielectric layer is formed and contact structures are formed to the source and drain regions. The inner dielectric spacer prevents an electrical short between the gate electrode and a contact structure that partially overlies the gate electrode by overlay variations during lithographic patterning of a corresponding contact via hole.

According to an aspect of the present disclosure, a semiconductor structure is provided. The semiconductor structure includes a gate dielectric located on a semiconductor substrate; at least one work function metal portion and a lower gate electrode portion in contact with the gate dielectric; an inner dielectric spacer overlying the gate dielectric, the at least one work function metal portion and the lower gate electrode portion; and an upper gate electrode portion in contact with a top surface of the lower gate electrode portion and inner sidewalls of the inner dielectric spacer.

According to another aspect of the present disclosure, a method of forming a semiconductor structure is provided. A gate cavity is formed over a semiconductor substrate, which is laterally surrounded by a planarization dielectric layer having a planar top surface. A gate dielectric, at least one work function metal portion and a gate electrode portion are formed within the gate cavity. Top surfaces of the gate electrode are coplanar with the planar top surface of the planarization dielectric layer. A recessed region is formed within the planarization dielectric layer by recessing the at least one work function metal portion and the gate electrode portion below the planar top surface of the planarization dielectric layer. A remaining portion of the gate electrode portion is a lower gate electrode portion. An inner dielectric spacer is formed at a periphery of the recessed region. An upper gate electrode is formed on a top surface of the lower gate electrode portion and inner sidewalls of the inner dielectric spacer.

### BRIEF DESCRIPTION OF THE SEVERAL VIEWS OF THE DRAWINGS

FIG. 1 is vertical cross-sectional view of an exemplary semiconductor structure after formation of disposable gate structures and formation of a planar dielectric surface on a planarization dielectric layer according to an embodiment of the present disclosure.

FIG. 2 is a vertical cross-sectional view of the exemplary semiconductor structure after removal of the disposable gate structures according to an embodiment of the present disclosure.

FIG. 3 is a vertical cross-sectional view of the exemplary semiconductor structure after formation of a gate dielectric layer according to an embodiment of the present disclosure.

FIG. 4 is a vertical cross-sectional view of the exemplary semiconductor structure after formation of a first work function material layer according to an embodiment of the present disclosure.

FIG. 5 is a vertical cross-sectional view of the exemplary semiconductor structure after patterning of the first work function material layer according to an embodiment of the present disclosure.

FIG. 6 is a vertical cross-sectional view of the exemplary semiconductor structure after formation of a second work function material layer and a first conductive material layer according to an embodiment of the present disclosure.

FIG. 7 is a vertical cross-sectional view of the exemplary semiconductor structure after planarization of the first conductive material layer and work function material layers according to an embodiment of the present disclosure.

FIG. 8 is a vertical cross-sectional view of the exemplary semiconductor structure after recessing of at least one work function metal portion and gate conductor portions according to an embodiment of the present disclosure.

FIG. 9 is a vertical cross-sectional view of the exemplary semiconductor structure after deposition of a conformal dielectric material layer according to an embodiment of the present disclosure.

FIG. 10A is a vertical cross-sectional view of the exemplary semiconductor structure after formation of inner dielectric spacers according to an embodiment of the present disclosure.

FIG. 10B is a top-down view of the exemplary semiconductor structure of FIG. 10A.

FIG. 11 is a vertical cross-sectional view of the exemplary semiconductor structure after formation of a second conductive material layer according to an embodiment of the present disclosure.

FIG. 12 is a vertical cross-sectional view of the exemplary semiconductor structure after planarization of the second conductive material layer according to an embodiment of the present disclosure.

FIG. 13 is a vertical cross-sectional view of the exemplary semiconductor structure after formation of a contact-level dielectric layer and various contact via structures according to an embodiment of the present disclosure.

FIG. 14 is a vertical cross-sectional view of a variation of the exemplary semiconductor structure.

### DETAILED DESCRIPTION

As stated above, the present disclosure relates to semiconductor structures having a replacement gate structure including a reversed dielectric spacer formed within a gate spacer and above a channel of a field effect transistor, and methods of manufacturing the same. Aspects of the present disclosure are now described in detail with accompanying figures. Like and corresponding elements mentioned herein and illustrated in the drawings are referred to by like reference numerals. The drawings are not necessarily drawn to scale.

As used herein, ordinals such as “first” and “second” are employed merely to distinguish similar elements, and different ordinals may be employed to designate a same element in the specification and/or claims.

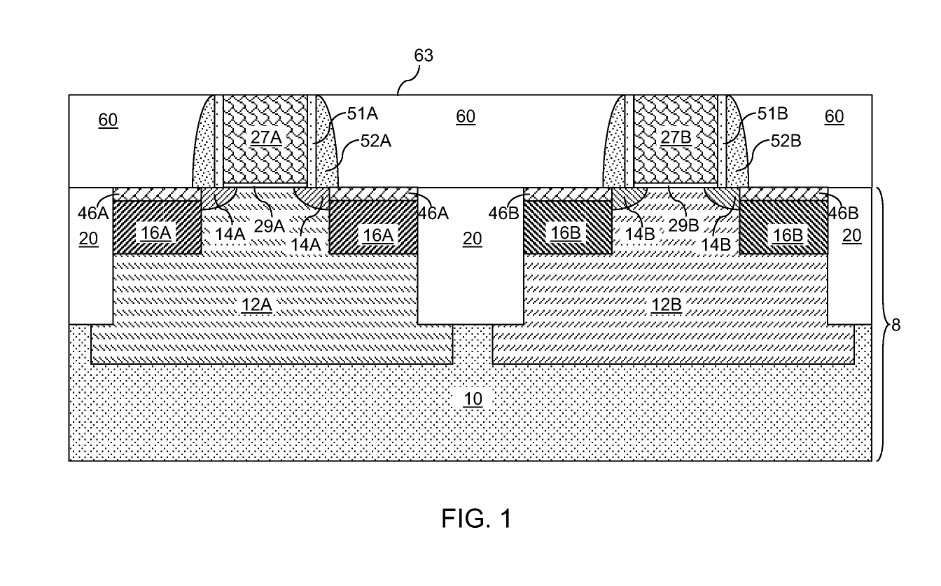

Referring to FIG. 1, an exemplary semiconductor structure according to an embodiment of the present disclosure includes a semiconductor substrate 8, on which various components of field effect transistors are formed. The semiconductor substrate 8 can be a bulk substrate including a bulk semiconductor material throughout, or a semiconductor-on-insulator (SOI) substrate (not shown) containing a top semiconductor layer, a buried insulator layer located under the top semiconductor layer, and a bottom semiconductor layer located under the buried insulator layer.

Various portions of the semiconductor material in the semiconductor substrate 8 can be doped with electrical dopants of n-type or p-type at different dopant concentration levels. For example, the semiconductor substrate 8 may include an underlying semiconductor layer 10, a first doped well 12A formed in a first device region (the region to the left in FIG. 1), and an second doped well 12B formed in a second device region (the region to the right in FIG. 1). Each of the first doped well 12A and the second doped well 12B can be independently doped with n-type electrical dopants or p-type electrical dopants. Thus, each of the first doped well 12A and the second doped well 12B can be an n-type well or a p-type well.

Shallow trench isolation structures 20 are formed to laterally separate each of the second doped well 12B and the first doped well 12A. Typically, each of the second doped well 12B and the first doped well 12A is laterally surrounded by a contiguous portion of the shallow trench isolation structures 20. If the semiconductor substrate 8 is a semiconductor-on-insulator substrate, bottom surfaces of the second doped well 12B and the first doped well 12A may contact a buried insulator layer (not shown), which electrically isolates each of the second doped well 12B and the first doped well 12A from other semiconductor portions of the semiconductor substrate 8 in conjunction with the shallow trench isolation structures 20.

A disposable dielectric layer and a disposable gate material layer are deposited and lithographically patterned to form disposable gate structures. For example, the disposable gate stacks may include a first disposable gate structure that is a stack of a first disposable dielectric portion 29A and a first disposable gate material portion 27A and a second disposable gate structure that is a stack of a second disposable dielectric portion 29B and a second disposable gate material portion 27B. The disposable dielectric layer includes a dielectric material such as a semiconductor oxide. The disposable gate material layer includes a material that can be subsequently removed selective to dielectric material such as a semiconductor material. The first disposable gate structure (29A, 27A) is formed over the first doped well 12A, and the second disposable gate structure (29B, 27B) is formed over the second doped well 12B. The height of the first disposable gate structure (29A, 27A) and the second disposable gate structure (29B, 27B) can be from 20 nm to 500 nm, and typically from 30 nm to 150 nm, although lesser and greater heights can also be employed.

First electrical dopants are implanted into portions of the first doped well 12A that are not covered by the first disposable gate structure (29A, 27A) to form first source and drain extension regions 14A. The second doped well 12B can be masked by a photoresist (not shown) during the implantation of the first electrical dopants to prevent implantation of the first electrical dopants therein. In one embodiment, the first electrical dopants have the opposite polarity of the polarity of doping of the first doped well 12A. For example, the first doped well 12A can be a p-type well and the first electrical dopants can be n-type dopants such as P, As, or Sb. Alternatively, the first doped well 12A can be an n-type well and the first electrical dopants can be p-type dopants such as B, Ga, and In.

Second electrical dopants are implanted into portions of the second doped well 12B that are not covered by the second disposable gate structure (29B, 27B) to form second source and drain extension regions 14B. The first doped well 12A can be masked by a photoresist (not shown) during the implantation of the second electrical dopants to prevent implantation of the second electrical dopants therein. For example, the second doped well 12B can be an n-type well and the second electrical dopants can be p-type dopants. Alternatively, the second doped well 12B can be a p-type well and the second electrical dopants can be n-type dopants.

At least one gate spacer is formed on outer sidewalls of each of the disposable gate structures (29A, 27A, 29B, 27B). For example, the at least one gate spacer can include a first inner gate spacer 51A formed around the first disposable gate structure (29A, 27A), a first outer gate spacer 52A formed around the first inner gate spacer 51A, a second inner gate spacer 51B formed around the second disposable gate structure (29B, 27B), and a second outer gate spacer 52B formed around the second inner gate spacer 51B. In one embodiment, the first and second inner gate spacers (51A, 51B) can have a same composition, and can be formed by conversion of vertical surface portions of the first and second disposable gate material portions (27A, 27B) into a dielectric material, for example, by oxidation and/or nitridation and/or by deposition of a conformal dielectric material layer and an anisotropic etch. In one embodiment, the first and second outer gate spacers (52A, 52B) can have a same composition, and can be formed by deposition of another conformal dielectric material layer and an anisotropic etch. The first and second inner gate spacers (51A, 51B) can include silicon oxide, silicon nitride, silicon oxynitride, or combinations thereof. The first and second outer gate spacers (52A, 52B) can include silicon oxide, silicon nitride, silicon oxynitride, porous or non-porous organosilicate glass, or combinations thereof.

Dopants having the same conductivity type as the first electrical dopants are implanted into portions of the first doped well 12A that are not covered by the first disposable gate structure (29A, 27A) and the first gate spacer 52A to form first source and drain regions 16A. The second doped well 12B can be masked by a photoresist (not shown) during this implantation to prevent undesired implantation therein. Similarly, dopants having the same conductivity type as the second electrical dopants are implanted into portions of the second doped well 12B that are not covered by the second disposable gate structure (29B, 27B) and the second gate spacer 52B to form second source and drain regions 16B. The first doped well 12A can be masked by a photoresist (not shown) during this implantation to prevent undesired implantation therein.

In some embodiments, the first source and drain regions 16A and/or the second source and drain regions 16B can be formed by replacement of the semiconductor material in the first doped well 12A and/or the semiconductor material in the second doped well 12B with a new semiconductor material having a different lattice constant. In this case, the new semiconductor material(s) is/are typically epitaxially aligned with (a) single crystalline semiconductor material(s) of the first doped well 12A and/or the semiconductor material in the second doped well 12B, and apply/applies a compressive stress or a tensile stress to the semiconductor material of the first doped well 12A and/or the semiconductor material in the second doped well 12B between the first source and drain extension regions 14A and/or between the second source and drain extension regions 14B.

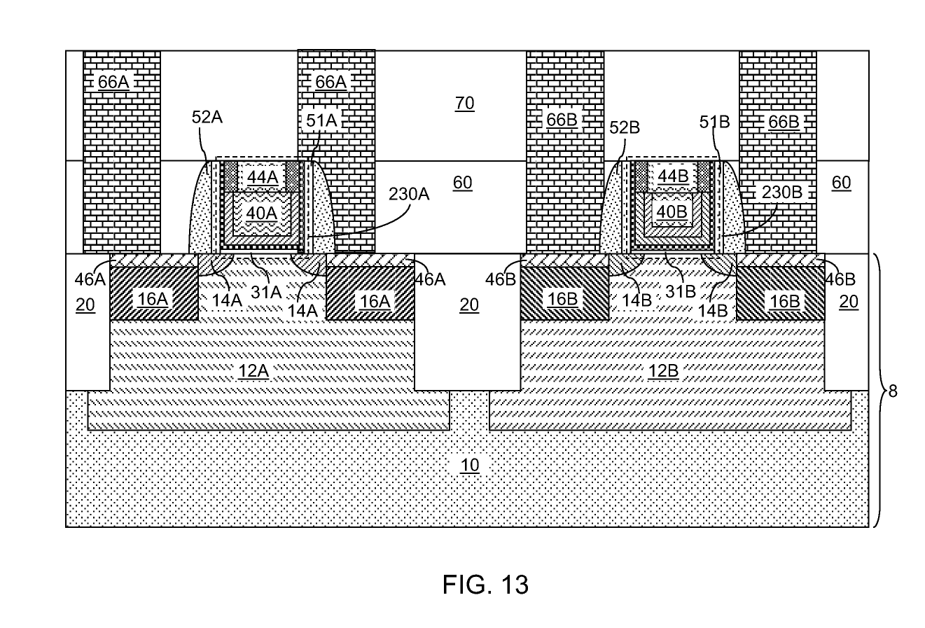

Optionally, first metal semiconductor alloy portions 46A and second metal semiconductor alloy portions 46B are formed on exposed semiconductor material on the top surface of the semiconductor substrate 8, for example, by deposition of a metal layer (not shown) and an anneal. Unreacted portions of the metal layer are removed selective to reacted portions of the metal layer. The reacted portions of the metal layer constitute the metal semiconductor alloy portions (46A, 46B), which can include a metal silicide portions if the semiconductor material of the first and second source and drain regions (16A, 16B) include silicon. Alternatively, formation of the first metal semiconductor alloy portions 46A and the second metal semiconductor alloy portions 46B may be performed in a subsequent processing step after formation of replacement gate structures and contact via holes through a stack of a contact-level dielectric layer 70 (See FIG. 13) and the planarization dielectric layer 60 and prior to formation of various contact via structures (66A, 66B; See FIG. 13).

A planarization dielectric layer 60 is deposited over the semiconductor substrate 8, the disposable gate structures (29A, 27A, 29B, 27B), and the at least one gate spacer (51A, 51B, 52A, 52B). Preferably, the planarization dielectric layer 60 includes a dielectric material that can be planarized, for example, by chemical mechanical planarization. For example, the planarization dielectric layer 60 can include a doped silicate glass, an undoped silicate glass (silicon oxide), and/or porous or non-porous organosilicate glass.

The planarization dielectric layer 60 is planarized above the topmost surfaces of the first and second disposable gate structures (29A, 27A, 29B, 27B), i.e., above the topmost surfaces of the first and second disposable gate material portions (27A, 27B). The planarization can be performed, for example, by chemical mechanical planarization (CMP). The planar topmost surface of the planarization dielectric layer 60 is herein referred to as a planar dielectric surface 63.

The combination of the first source and drain extension regions 14A, the first source and drain regions 16A, and the first doped well 12A can be employed to subsequently form a first field effect transistor. The combination of the second source and drain extension regions 14B, the second source and drain regions 16B, and the second doped well 12B can be employed to subsequently form a second field effect transistor.

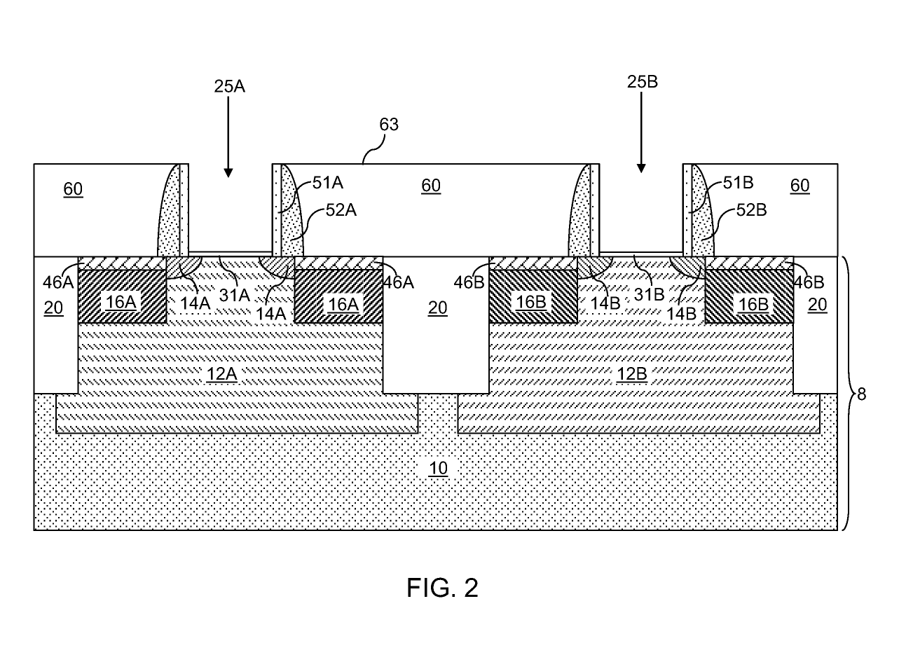

Referring to FIG. 2, the first disposable gate structure (29A, 27A) and the second disposable gate structure (29B, 27B) are removed by at least one etch. The at least one etch can be a recess etch, which can be an isotropic etch or anisotropic etch. The removal of the disposable gate structures (27A, 27B, 29A, 29B) can be performed employing an etch chemistry that is selective to the at least one gate spacer (51A, 51B, 52A, 52B). In one embodiment, the etch employed to remove the first and second disposable gate material portions (27A, 27B) can be selective to the dielectric materials of the planarization dielectric layer 60, and the at least one gate spacers (51A, 51B, 52A, 52B). A first gate cavity 25A and a recessed region 25B are formed in volumes from which the first disposable gate structure (29A, 27A) and the second disposable gate structure (29B, 27B) are removed, respectively. The semiconductor surfaces above the first channel and the second channel can be physically exposed at the bottom of the first and second gate cavities (25A, 25B). The first gate cavity 25A is laterally enclosed by the first inner gate spacer 51A and the first outer gate spacer 52A, and the recessed region 25B is laterally enclosed by the second inner gate spacer 51B and the second inner gate spacer 52B.

Optionally, a first interfacial dielectric layer 31A can be formed on the exposed surface of the first doped well 12A by conversion of the exposed semiconductor material into a dielectric material, and a second interfacial dielectric layer 31B can be formed on the exposed surface of the second doped well 12B by conversion of the exposed semiconductor material into the dielectric material. Each of the first and second interfacial dielectric layers (31A, 31B) can be a semiconductor-element-containing dielectric layer. The formation of the interfacial dielectric layers (31A, 31B) can be effected by thermal conversion, chemical conversion or plasma treatment. If the semiconductor material of the first doped well 12A and the second doped well 12B includes silicon, the interfacial dielectric layers (31A, 31B) can include silicon oxide or silicon oxynitride. The interfacial dielectric layers (31A, 31B) contact a semiconductor surface underneath and gate dielectrics to be subsequently deposited thereupon. In one embodiment, the first interfacial dielectric layer 31A and the second interfacial dielectric layer 31B can have a same composition and a same thickness.

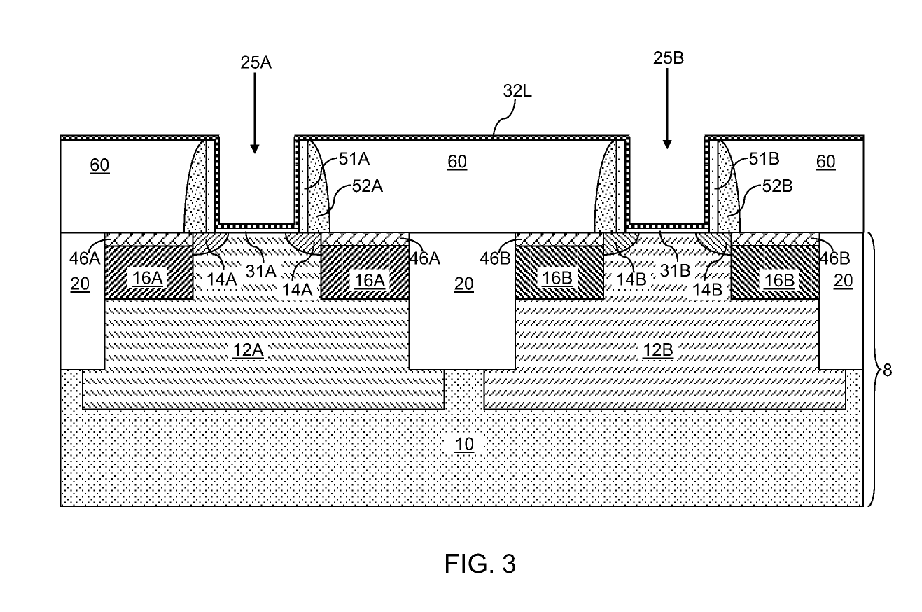

Referring to FIG. 3, a gate dielectric layer 32L is deposited on the bottom surface and sidewall surfaces of each gate cavity (25A, 25B) and over the planarization dielectric layer 60. Specifically, the gate dielectric layer 32L can be deposited on the first and second interfacial dielectric layers (31A, 31B) and on inner sidewalls of the first and second gate spacers (52A, 52B). The gate dielectric layer 32L can be deposited as a contiguous gate dielectric layer that contiguously covers all top surfaces of the planarization dielectric layer 60, all inner sidewall surfaces of the first and second inner gate spacers (51A, 51B), and all top surfaces of the first and second interfacial dielectric layers (31A, 31B).

The gate dielectric layer 32L can be a high dielectric constant (high-k) material layer having a dielectric constant greater than 3.9. The gate dielectric layer 32L can include a dielectric metal oxide, which is a high-k material containing a metal and oxygen, and is known in the art as high-k gate dielectric materials. Dielectric metal oxides can be deposited by methods well known in the art including, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), etc.

Exemplary high-k dielectric material include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from 0.5 to 3 and each value of y is independently from 0 to 2. The thickness of the gate dielectric layer 32L, as measured at horizontal portions, can be from 0.9 nm to 6 nm, and from 1.0 nm to 3 nm. The gate dielectric layer 32L may have an effective oxide thickness on the order of or less than 2 nm. In one embodiment, the gate dielectric layer 32L is a hafnium oxide (HfO₂) layer.

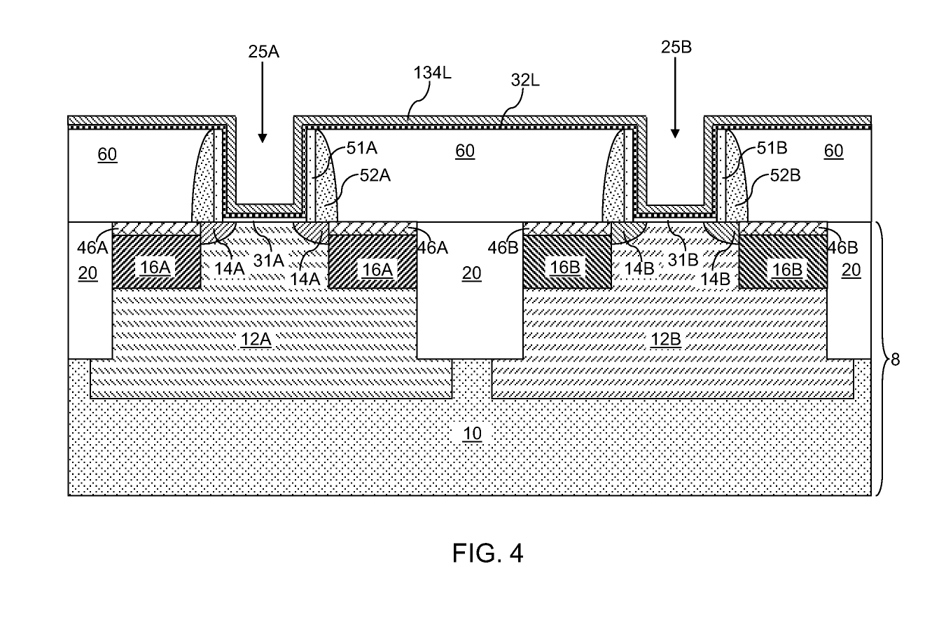

Referring to FIG. 4, a first work function material layer 134L is deposited on the gate dielectric layer 32L. The material of the first work function material layer 134L has a first work function, and can be selected from any work function material known in the art. The first work function material layer 134L can include an elemental only, or can include a metallic compound, which includes a metal and a non-metal element. The metallic compound is selected to optimize the performance of the second field effect transistor to be subsequently formed in the second device region employing the second source and drain extension regions 14B, the second source and drain regions 16B, and the second doped well 12B. The metallic compound can be selected from tantalum carbide, metallic nitrides, and a hafnium-silicon alloy. Exemplary metallic nitrides include titanium nitride, tantalum nitride, tungsten nitride, and combinations and alloys thereof.

The first work function material layer 134L can be formed, for example, by physical vapor deposition, chemical vapor deposition, or atomic layer deposition (ALD). The thickness of the first work function material layer 134L is typically set at a value from 1 nm to 30 nm, and more typically, from 2 nm to 10 nm, although lesser and greater thicknesses can also be employed.

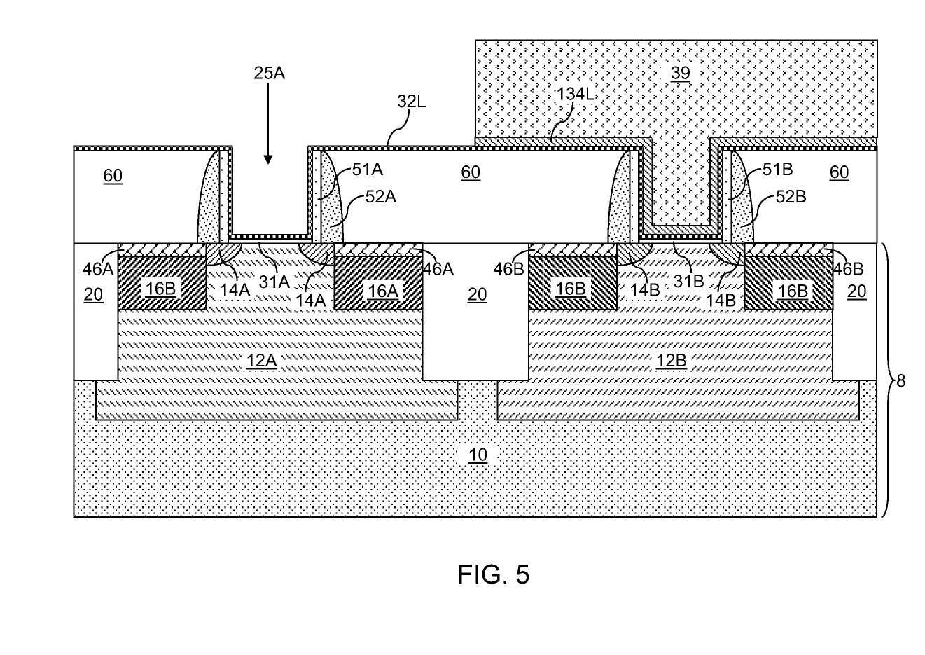

Referring to FIG. 5, a photoresist layer 39 is applied and lithographic patterned so that the photoresist layer 39 covers the area over the second doped well 12B, while the top surface of the first work function material layer 134L is exposed over the first doped well 12A. The pattern in the photoresist layer 39 is transferred into the first work function material layer 134L by an etch. The portion of the first work function material layer 134L within the first gate cavity 25A is removed employing the first photoresist 39 as an etch mask. The etch chemistry employed to remove physically exposed portions of the first work function material layer 134L can be selective to the dielectric material of the gate dielectric layer 32L.

Subsequently, the photoresist layer 39 is removed, for example, by ashing or wet etching. After the patterning of the first work function material layer 134L, a remaining portion of the first work function material layer 134L can be present only in the second device region, and not present in the first device region. Correspondingly, the first work function material layer 134L is present in the recessed region 25B (See FIG. 4), but is not present in the first gate cavity 25A. The photoresist layer 39 is subsequently removed, for example, by ashing or wet chemical etching.

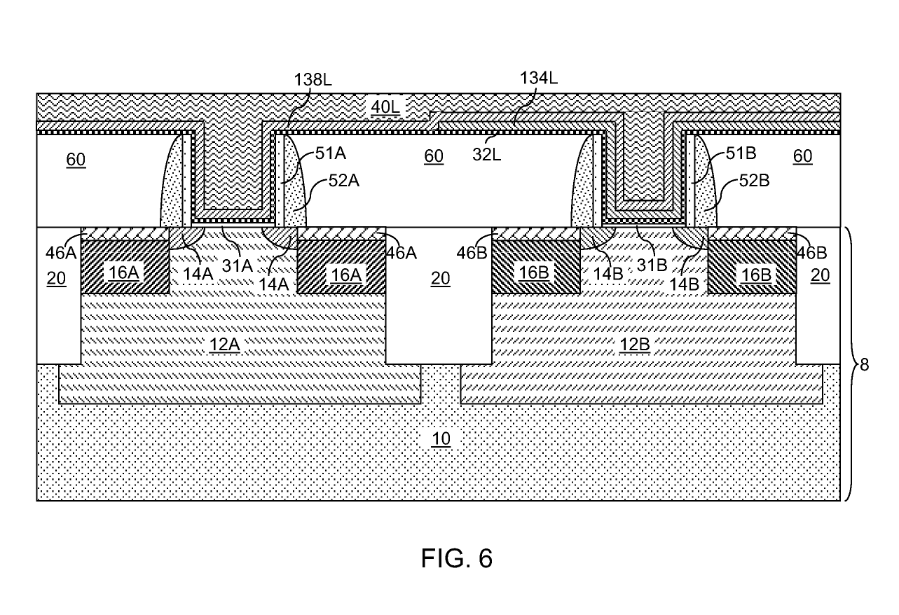

Referring to FIG. 6, a second work function material layer 138L is deposited. The second work function material layer 138L includes a second metal having a second work function, which can be different from the first work function. The material of the second work function material layer 138L can be selected from any work function material known in the art. The material of the second work function material layer 138L can be selected to optimize the performance of the first field effect transistor to be subsequently formed in the first device region employing the first source and drain extension regions 14A, the first source and drain regions 16A, and the first doped well 12B.

The second work function material layer 138L can be formed, for example, by physical vapor deposition, chemical vapor deposition, or atomic layer deposition (ALD). The thickness of the second work function material layer 138L is typically set at a value from 2 nm to 100 nm, and more typically, from 3 nm to 10 nm, although lesser and greater thicknesses can also be employed.

A conductive material layer 40L can be deposited on the second work function material layer 138L. The conductive material layer 40L can include a conductive material deposited by physical vapor deposition, chemical vapor deposition, and/or electroplating. For example, the conductive material layer 40L can be an aluminum layer, a tungsten layer, an aluminum alloy layer, or a tungsten alloy layer, and can be deposited by physical vapor deposition or chemical vapor deposition. The thickness of the conductive material layer 40L, as measured in a planar region of the conductive material layer 40L above the top surface of the planarization dielectric layer 60, can be from 30 nm to 500 nm, although lesser and greater thicknesses can also be employed. In one embodiment, the conductive material layer 40L consists essentially of a single elemental metal such as Al, or W. For example, the conductive material layer 40L can consist essentially of aluminum. If the conductive material layer 40L consists essentially of aluminum, the conductive material layer 40L can be reflowed to fill any void within the gate cavities (25A, 25B; See FIG. 5).

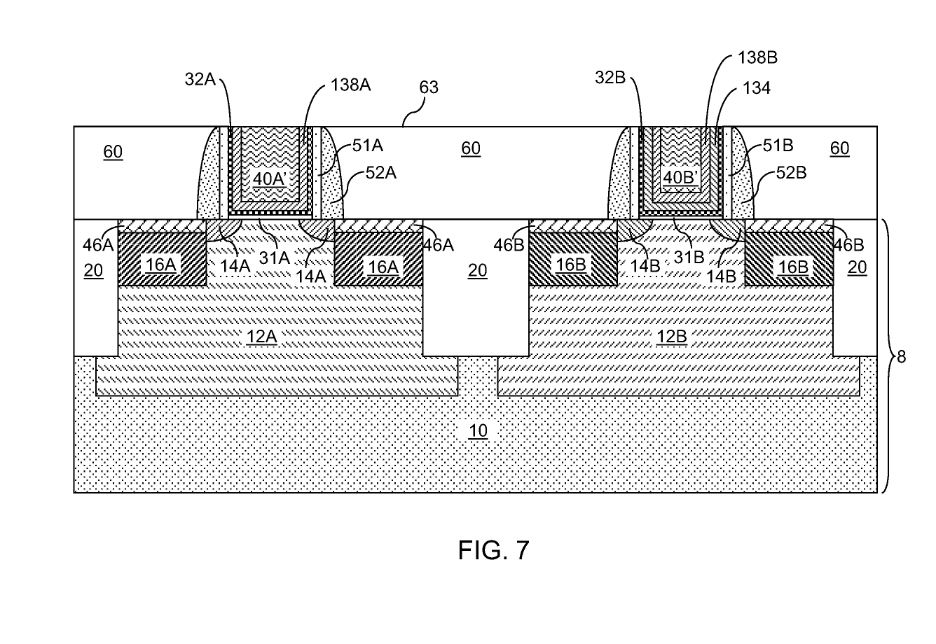

Referring to FIG. 7, portions of the gate conductor layer 40L, the second work function material layer 138L, the first work function material layer 134L, and the gate dielectric layer 32L are removed from above the planar dielectric surface 63 of the planarization dielectric layer 60 by a planarization process. Replacement gate stacks are formed by the first and second interfacial dielectric layers (31A, 31B) and various remaining portions of the gate conductor layer 40L, the second work function material layer 138L, the first work function material layer 34L, and the gate dielectric layer 32L.

The replacement gate stacks include a first replacement gate stack located in the first device region and a second replacement gate stack located in the second device region. Each replacement gate stack overlies a channel region of a field effect transistor. The first replacement gate stack and the second replacement gate stack are formed concurrently.

The first replacement gate stack includes the first interfacial dielectric layer 31A, a first gate dielectric 32A which is a remaining portion of the gate dielectric layer 32L, a work function material portion 138A which is a remaining portion of the second work function material layer 138L, and a first gate conductor portion 40A′ which is a remaining portion of the gate conductor layer 40L. The work function material portion 138A and the first gate conductor portion 40A′ collectively constitute a first gate electrode (138A, 40A′). The second replacement gate stack includes the second interfacial dielectric layer 31B, a second gate dielectric 32B which is a remaining portion of the gate dielectric layer 32L, a first work function material portion 134 which is a remaining portion of the first work function material layer 134L, a second work function material portion 138B which is a remaining portion of the second work function material layer 138L, and a second gate conductor portion 40B′ which is a remaining portion of the gate conductor layer 40L. The first work function material portion 134, the second work function material portion 138B, and the second gate conductor portion 40B′ collectively constitute a second gate electrode (134, 138B, 40B′).

The top surface of the first gate electrode (138A, 40A′) and the top surface of the second gate electrode (134, 138B, 40B′) are coplanar with the top planar top surface of the planarization dielectric layer 60. The first gate dielectric 32A is a U-shaped gate dielectric including a horizontal portion that underlies the first gate electrode (138A, 40A′) and a vertical portion that laterally surrounds the first gate electrode (138A, 40A′). The second gate dielectric 32B is a U-shaped gate dielectric including a horizontal portion that underlies the second gate electrode (134, 138B, 40B′) and a vertical portion that laterally surrounds the second gate electrode (134, 138B, 40B′). The outer sidewalls of the first gate dielectric 32A is in contact with the inner vertical sidewall of the first inner gate spacer 51A. The outer sidewalls of the second gate dielectric 32B are in contact with the inner vertical sidewall of the second inner gate spacer 51B.

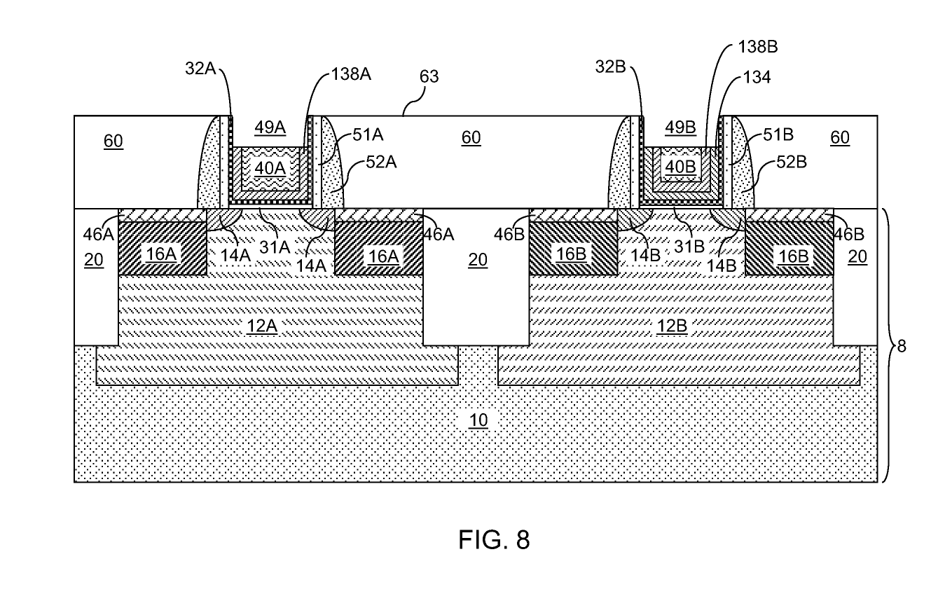

Referring to FIG. 8, an upper portion of the first gate electrode (138A, 40A′) and the upper portion of the second gate electrode (134, 138B, 40B′) are vertically recessed from the planar dielectric surface 63 of the planarization dielectric layer 60 by an etch, which can be an isotropic etch or an anisotropic etch. A first recessed region 49A is formed above the remaining portions of the first gate electrode, which includes a first lower gate electrode portion 40A and a remaining portion of the work function material portion 138A. The first lower gate electrode portion 40A is a remaining portion of the first gate conductor portion 40A′. A second recessed region 49B is formed above the remaining portions of the second gate electrode, which includes a second lower gate electrode portion 40B, a remaining portion of the first work function material portion 134, and a remaining portion of the second work function material portion 138B. The second lower gate electrode portion 40B is a remaining portion of the second gate conductor portion 40B′. The first recessed region 49A and the second recessed region 49B are formed within the planarization dielectric layer 60 by recessing upper portions of the first gate electrode and the second gate electrode, respectively, below the planar top surface 63 of the planarization dielectric layer 60. The ratio of the depth of the first and second recessed regions (49A, 49B) to the thickness of the planarization dielectric layer 60 can be from 0.1 to 0.6, although lesser and greater ratios can also be employed.

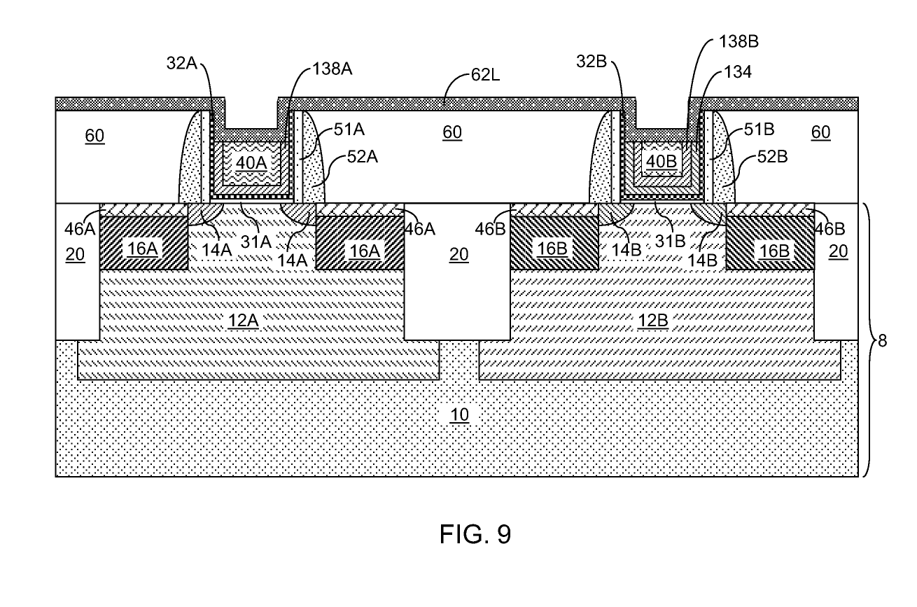

Referring to FIG. 9, a conformal dielectric material layer 62L is deposited within the first and second recessed regions (49A, 49B) and over the planarization dielectric layer 60. The conformal dielectric material layer 62L includes a dielectric material such as silicon nitride, a dielectric metal oxide layer, or silicon nitride. Exemplary materials that can be employed for the dielectric metal oxide layer include, for example, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from 0.5 to 3 and each value of y is independently from 0 to 2. The conformal dielectric material layer 62L can be formed, for example, by chemical vapor deposition (CVD) or atomic layer deposition (ALD). The thickness of the conformal dielectric material layer 62L can be, for example, from 1 nm to 40% of the lesser of the width of the first recessed region 49A and the width of the second recessed region 49B as formed at the processing step of FIG. 8.

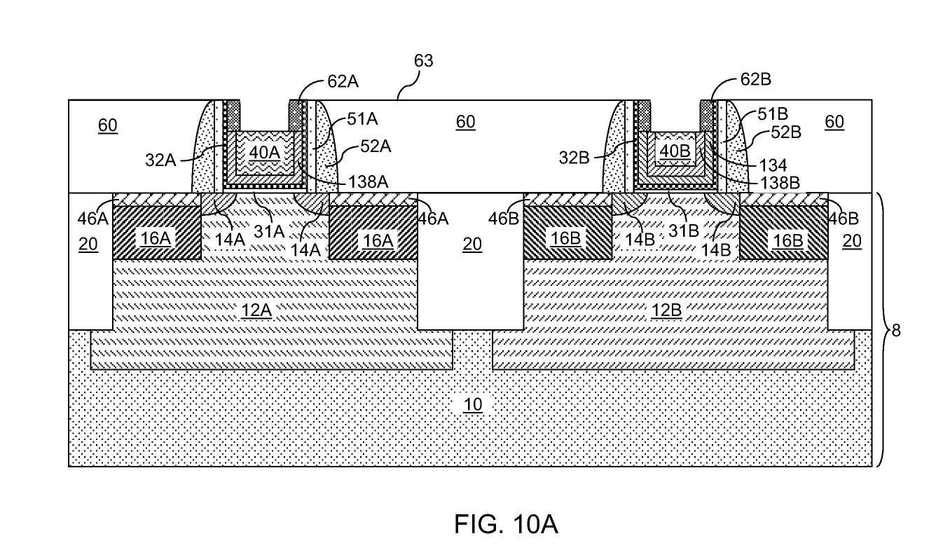

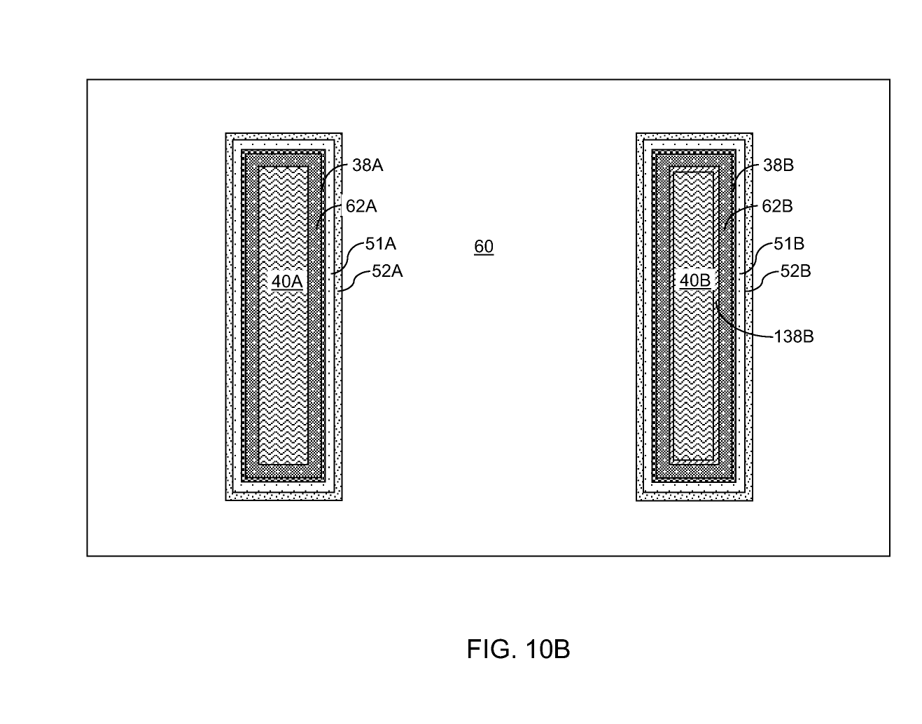

Referring to FIGS. 10A and 10B, an anisotropic etch is performed to remove horizontal portions of the conformal dielectric material layer 62L. The anisotropic etch can be selective to the materials of the first gate electrode (138A, 40A) and the second gate electrode (134, 138B, 40B). Optionally, the anisotropic etch can be selective to the dielectric materials of the planarization dielectric layer 60, the first and second gate dielectrics (32A, 32B), the inner gate spacers (51A, 51B), and the outer gate spacers (52A, 52B). The remaining vertical portion of the conformal dielectric material layer over the first gate electrode (138A, 40A) constitutes a first inner dielectric spacer 62A, and the remaining vertical portion of the conformal dielectric material layer over the second gate electrode (134, 138B, 40B) constitutes a second inner dielectric spacer 62B.

Each of the first inner dielectric spacer 62A and the second dielectric spacer 62B is located below the horizontal plane of the planar top surface 63 of the planarization dielectric layer 60. The first inner dielectric spacer 62A and the second inner dielectric spacer 62B are formed within the first recessed region 49A and the second recessed region 49B as formed at the processing step of FIG. 8. Thus, the first inner dielectric spacer 62A and the second inner dielectric spacer 62B are formed on the inner sidewalls of the first gate dielectric 32A and the on the inner sidewalls of the second gate dielectric 32B, respectively, and are herein referred to reversed dielectric spacers. Each of the first inner dielectric spacer 62A and the second inner dielectric spacer 62B is topologically homeomorphic to a torus, i.e., can be contiguously stretched into the shape of a torus without forming a new hole or destroying an existing hole. In one embodiment, each of the first inner dielectric spacer 62A and the second inner dielectric spacer 62B can have a horizontal cross-sectional shape of a rectangular ring having the same width throughout the entire periphery thereof.

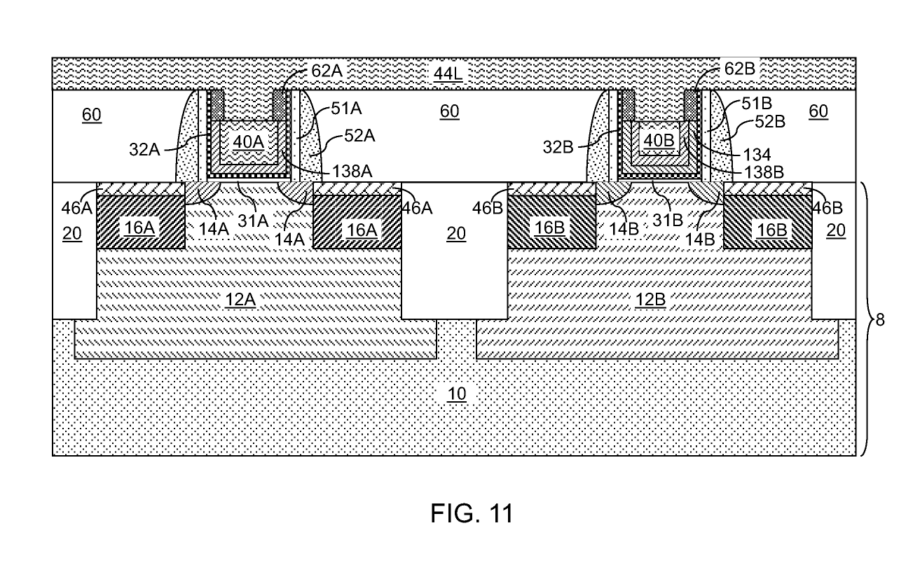

Referring to FIG. 11, a second conductive material layer 44L including a conductive material is deposited to fill the space laterally surrounded by the first inner dielectric spacer 62A and the space laterally surrounded by the second inner dielectric spacer 62B. The second conductive material layer 44L can include a conductive material deposited by physical vapor deposition, chemical vapor deposition, and/or electroplating. For example, the second conductive material layer 44L can be an aluminum layer, a tungsten layer, an aluminum alloy layer, or a tungsten alloy layer, and can be deposited by physical vapor deposition. The thickness of the second conductive material layer 44L, as measured in a planar region of the conductive material layer 44L above the top surface of the planarization dielectric layer 60, can be from 30 nm to 500 nm, although lesser and greater thicknesses can also be employed. In one embodiment, the second conductive material layer 44L consists essentially of a single elemental metal such as Al, or W. For example, the second conductive material layer 44L can consist essentially of aluminum. If the second conductive material layer 44L consists essentially of aluminum, the conductive material layer 44L can be reflowed to fill any void above the first and second lower gate electrode portions (40A, 40B). The conductive material of the second conductive material layer 44L can be the same as, or can be different from, the conductive material of the first and second lower gate electrode portions (40A, 40B).

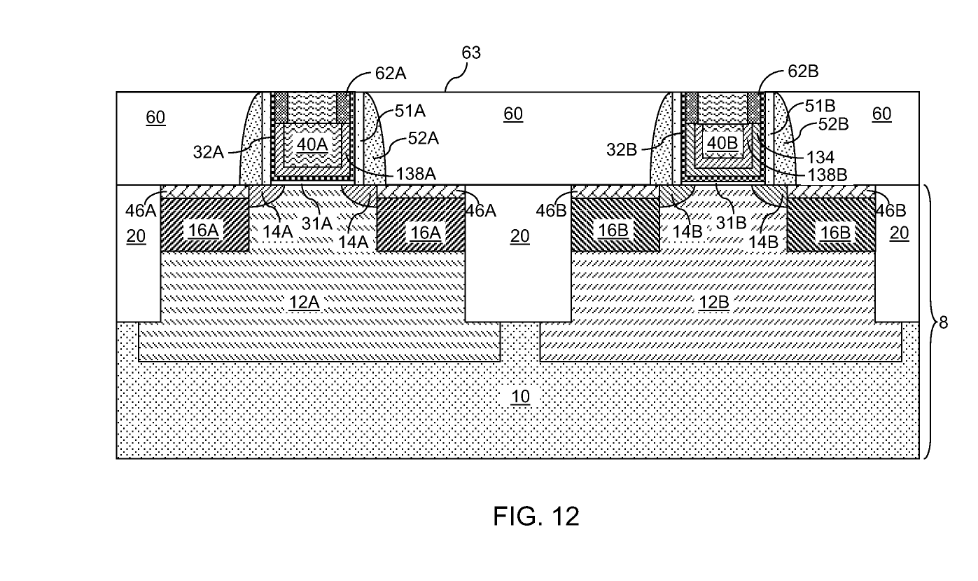

Referring to FIG. 12, the second conductive material layer 44L is planarized to remove the conductive material from above the planar top surface 63 of the planarization dielectric layer 60. In one embodiment, the second conductive material layer 44L can be planarized employing the planarization dielectric layer 60 as a stopping layer. The first gate electrode (138A, 40A, 44A) includes a first upper gate electrode portion 44A, which is a remaining portion of the second conductive material layer 44L. The second gate electrode (134, 138B, 40B, 44B) includes a second upper gate electrode portion 44B, which is a remaining portion of the second conductive material layer 44L.

The exemplary structure of FIG. 12 is a semiconductor structure that includes a gate dielectric (e.g., the combination of the first interfacial dielectric layer 31A and the first gate dielectric 32A or the combination of the second interfacial dielectric layer 31B and the second gate dielectric 32B) located on a semiconductor substrate 8, a lower gate electrode portion (e.g., the first lower gate electrode portion 40A or the second lower gate electrode portion 40B) in contact with the gate dielectric, an inner dielectric spacer (e.g., the first inner dielectric spacer 62A or the second inner dielectric spacer 62B) overlying the gate dielectric and the lower gate electrode portion, and an upper gate electrode portion (e.g., the first upper gate electrode portion 44A or the second upper gate electrode portion 44B) in contact with a top surface of the lower gate electrode portion and inner sidewalls of the inner dielectric spacer.

The at least one gate spacer (e.g., the combination of the first inner gate spacer 51A and the first outer gate spacer 52A or the combination of the second inner gate spacer 51B and the second outer gate spacer 52B) has an inner vertical sidewall (e.g., the inner vertical sidewall of the first inner gate spacer 51A or the second inner gate spacer 51B). The outer periphery of the inner dielectric spacer (e.g., the first inner dielectric spacer 62A or the second dielectric spacer 62B) is in contact within an upper portion of the inner vertical sidewall.

The gate dielectric can include a U-shaped gate dielectric (e.g., the first gate dielectric 32A or the second gate dielectric 32B) including a horizontal portion that underlies the lower gate electrode portion and a vertical portion that laterally surrounds the gate electrode portion. The outer sidewalls of each U-shaped gate dielectric are in contact with the inner vertical sidewall of the first inner gate spacer 51A or the second inner gate spacer 51B.

The planarization dielectric layer 60 overlies the semiconductor substrate 8 and embeds the at least one gate spacer (51A, 51B, 52A, 52B). The topmost surface of each of the at least one gate spacer (51A, 51B, 52A, 52B) can be coplanar with the planar top surface 63 of the planarization dielectric layer 60. In one embodiment, the inner dielectric spacers (62A, 62B) can be employed as a stopping layer for planarization of the second conductive material layer 44L. In this case, the topmost surface of the inner dielectric spacers (62A, 62B) can be coplanar with the planar top surface 63 of the planarization dielectric layer 60.

In one embodiment, each of the inner dielectric spacers (62A, 62B) can have a uniform lateral thickness, and the upper gate electrode portion (44A or 44B) embedded therein is laterally spaced from at least one gate spacer (e.g., the combination of the first inner gate spacer 51A and the first outer gate spacer 52A or the combination of the second inner gate spacer 51B and the second outer gate spacer 52B) by the inner dielectric spacer (62A, 62B).

In one embodiment, a vertical surface of a gate dielectric (e.g., the combination of the first interfacial dielectric layer 31A and the first gate dielectric 32A or the combination of the second interfacial dielectric layer 31B and the second gate dielectric 32B) can be adjoined to, and can be vertically coincident with, an outer vertical surface of an inner dielectric spacer (e.g., the first inner dielectric spacer 62A or the second inner dielectric spacer 62B). In one embodiment, vertical surfaces of the gate dielectric and outer vertical surfaces of the inner dielectric spacer can contact an entirety of inner vertical sidewalls of the at least one gate spacer (e.g., the combination of the first inner gate spacer 51A and the first outer gate spacer 52A or the combination of the second inner gate spacer 51B and the second outer gate spacer 52B). Each inner dielectric spacer (e.g., the first inner dielectric spacer 62A or the second inner dielectric spacer 62B) is in contact with a gate dielectric (e.g., the combination of the first interfacial dielectric layer 31A and the first gate dielectric 32A or the combination of the second interfacial dielectric layer 31B and the second gate dielectric 32B) and at least one work function material portion (e.g., the work function material portion 138A, the first work function material portion 134, or the second work function material portion 138B).

Referring to FIG. 13, a contact-level dielectric layer 70 is deposited over the planarization dielectric layer 60. Various contact via structures can be formed, for example, by formation of contact via cavities by a combination of lithographic patterning and an anisotropic etch followed by deposition of a conductive material and planarization that removes an excess portion of the conductive material from above the contact-level dielectric layer 70. The various contact via structures can include, for example, first active region contact via structures 66A and second active region contact via structures 66B. Each of the first and second active region contact via structures (66A, 66B) can contact a source node or a drain node of a field effect transistor.

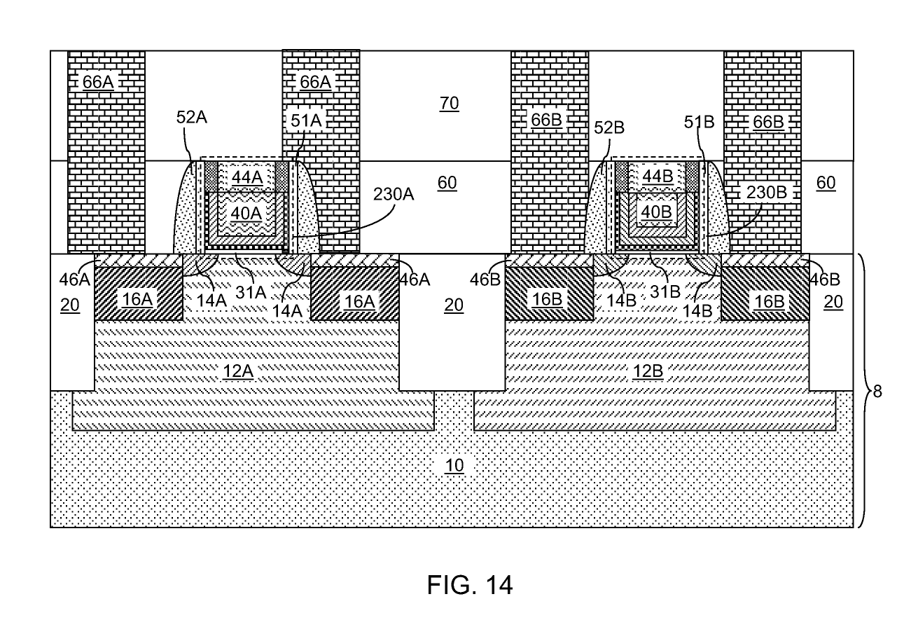

Referring to FIG. 14, a variation of the exemplary structure is derived from the exemplary structure by removing physically exposed portions of the first gate dielectric 31A within the first gate cavity 49A and by removing physically exposed portions of the second gate dielectric 31B within the second gate cavity 49B at the processing step of FIG. 8. Subsequently, the processing steps of FIGS. 9-13 can be performed.

In the exemplary structure, the first active region contact via structures 66A are illustrated as laterally offset from target locations due to significant overlay variations during the patterning of the contact via cavities over the first field effect transistor including the first gate electrode (138A, 40A, 44A), and the second active region contact via structures 66B are illustrated as structures formed at target locations. The inner dielectric spacers (62A, 62B) of the present disclosure does not adversely affect the electrical contact between an active region contact via structure formed at a target position and any component of a field effect transistor as in the case of the second active region contact via structures 66B. The inner dielectric spacers (62A, 62B) of the present disclosure can prevent the electrical contact between an active region contact via structure formed with a significant overlay error and a gate electrode of a field effect transistor as in the case of the first active region contact via structures 66A. While the first active region contact via structures 66A and second active region contact via structures 66B illustrate two exemplary cases of overlay variations, the structures of the present disclosure can be employed to reduce electrical shorts for a given level of statistical overlay variations for the lithography process for patterning the contact via cavities.

Thus, each inner dielectric spacer (e.g., the first inner dielectric spacer 62A or the second inner dielectric spacer 62B) provides protection against an electrical short between one of the contact via structures (66A, 66B) and a gate electrode (e.g., the first gate electrode (138A, 40A, 44A) or the second gate electrode (134, 138B, 40B, 44B)) by providing etch selectivity to the etch chemistry employed to form the contact via cavities.

While the disclosure has been described in terms of specific embodiments, it is evident in view of the foregoing description that numerous alternatives, modifications and variations will be apparent to those skilled in the art. Each of the various embodiments of the present disclosure can be implemented alone, or in combination with any other embodiments of the present disclosure unless expressly disclosed otherwise or otherwise impossible as would be known to one of ordinary skill in the art. Accordingly, the disclosure is intended to encompass all such alternatives, modifications and variations which fall within the scope and spirit of the disclosure and the following claims.

1. A semiconductor structure comprising:
a gate dielectric located on a semiconductor substrate;
a lower gate electrode portion in contact with said gate dielectric;
an inner dielectric spacer overlying said gate dielectric and said lower gate electrode portion;
an upper gate electrode portion in contact with a top surface of said lower gate electrode portion and inner sidewalls of said inner dielectric spacer; and
at least one gate spacer laterally surrounding said inner dielectric spacer, wherein a bottommost surface of said inner dielectric spacer is located above a horizontal plane including a bottommost surface of said at least one gate spacer.

2. The semiconductor structure of claim 1, wherein said at least one gate spacer has an inner vertical sidewall, wherein an outer periphery of said inner dielectric spacer is laterally enclosed within a periphery of an upper portion of said inner vertical sidewall.

3. The semiconductor structure of claim 2, wherein said gate dielectric comprises a U-shaped gate dielectric including a horizontal portion that underlies said lower gate electrode portion and a vertical portion that laterally surrounds at least said lower gate electrode portion.

4. The semiconductor structure of claim 3, wherein outer sidewalls of said U-shaped gate dielectric are in contact with at least a lower portion of said inner vertical sidewall.

5. The semiconductor structure of claim 2, further comprising a planarization dielectric layer overlying said semiconductor substrate and embedding said at least one gate spacer.

6. The semiconductor structure of claim 5, wherein a topmost surface of said at least one gate spacer is coplanar with a top surface of said planarization dielectric layer.

7. The semiconductor structure of claim 6, wherein a topmost surface of said inner dielectric spacer is coplanar with said top surface of said planarization dielectric layer.

8. The semiconductor structure of claim 2, wherein said inner dielectric spacer has a uniform lateral thickness, and said upper gate electrode portion is laterally spaced from said at least one gate spacer by said inner dielectric spacer.

9. The semiconductor structure of claim 2, wherein a vertical surface of said gate dielectric is adjoined to, and is vertically coincident with, an outer vertical surface of said inner dielectric spacer.

10. The semiconductor structure of claim 2, wherein vertical surfaces of said gate dielectric and outer vertical surfaces of said inner dielectric spacer contact an entirety of inner vertical sidewalls of said at least one gate spacer.

11. The semiconductor structure of claim 1, wherein said inner dielectric spacer is in contact with said gate dielectric and said lower gate electrode portion.

12. The semiconductor structure of claim 1, wherein said upper gate electrode portion and said lower gate electrode portion comprise different conductive materials.

13. The semiconductor structure of claim 1, wherein said upper gate electrode portion and said lower gate electrode portion comprise a same conductive material.

14. A method of forming a semiconductor structure comprising:
forming a gate cavity laterally surrounded by at least one gate spacer and a planarization dielectric layer having a planar top surface over a semiconductor substrate;
forming a gate dielectric and a gate electrode portion within said gate cavity, wherein top surfaces of said gate electrode are coplanar with said planar top surface of said planarization dielectric layer;
forming a recessed region within said planarization dielectric layer by recessing said gate electrode portion below said planar top surface of said planarization dielectric layer, wherein a remaining portion of said gate electrode portion is a lower gate electrode portion;
forming an inner dielectric spacer at a periphery of said recessed region, wherein a bottommost surface of said inner dielectric spacer is formed above a horizontal plane including a bottommost surface of said at least one gate spacer; and
forming an upper gate electrode on a top surface of said lower gate electrode portion and inner sidewalls of said inner dielectric spacer.

15. The method of claim 14, wherein said forming of said gate cavity comprises:
forming a disposable gate structure on said semiconductor substrate;
forming said planarization dielectric layer over said semiconductor substrate; and
removing said disposable gate structure selective to said planarization dielectric layer, wherein said gate cavity is formed in a volume from which said disposable gate structure is removed.

16. The method of claim 15, wherein said at least one gate spacer is located on outer sidewalls of said disposable gate structure, wherein said planarization dielectric layer is formed on said at least one gate spacer, wherein said removal of said disposable gate structure is performed employing an etch chemistry that is selective to said at least one gate spacer.

17. The method of claim 16, further comprising:
depositing a contact-level dielectric layer over said planarization dielectric layer;
forming a contact hole through said contact-level dielectric layer employing an etch chemistry that is selective to said inner dielectric spacer and said at least one gate spacer; and
forming a contact via structure by filling said contact hole with a conductive material.

18. The method of claim 14, wherein said forming of said inner dielectric spacer comprises:
depositing a conformal dielectric layer within said recessed region and over said planarization dielectric layer; and
removing horizontal portions of said conformal dielectric layer with an anisotropic etch, wherein a remaining portion of said conformal dielectric layer is said inner dielectric spacer.

19. The method of claim 14, wherein said forming of said upper gate electrode comprises:
depositing a conductive material within said recessed region and over said inner dielectric spacer and said planarization dielectric layer; and
planarizing said conductive material employing said planarization dielectric layer as a stopping layer.

20. The method of claim 14, wherein said forming of said gate dielectric and said gate electrode portion comprises:
depositing a gate dielectric layer on a bottom surface and sidewall surfaces of said gate cavity;
depositing a conductive material on said gate dielectric layer; and
removing portions of said gate dielectric layer and said conductive material from above said planar top surface of said planarization dielectric layer.
